(19) United States
(12) Patent Application Publication
(10) Pub. No.: US 2015/0167152 A1
(43) Pub. Date: Jun. 18, 2015

(54) METHOD OF FORMING AN ORGANIC LIGHT EMITTING DEVICE

(71) Applicant: Cambridge Display Technology Limited, Godmanchester (GB)

(72) Inventors: William Young, Cambridge (GB); Ilaria Grizzi, Godmanchester (GB)

(21) Appl. No.: 14/402,898

(22) PCT Filed: May 17, 2013
(86) PCT No.: PCT/GB2013/000225

§ 371 Date: Nov. 21, 2014

(30) Foreign Application Priority Data
May 28, 2012 (GB) 1209428.0

(51) Int. Cl. C23C 14/34; H01L 51/50; H01L 51/52; H01L 51/00

(52) U.S. Cl. CPC C23C 14/3414; H01L 51/0021; H01L 51/0097; H01L 51/5088; H01L 51/5215

(57) ABSTRACT

A method of forming an organic light-emitting device comprising an anode, a cathode and at least one light-emitting layer between the anode and the cathode, the method comprising the steps of: providing an anode layer supported on a surface of the substrate, wherein the anode layer comprises indium tin oxide formed by sputtering indium-tin oxide onto the substrate surface at a substrate surface temperature of less than 100° C., applying the at least one light-emitting layer and the cathode over the anode layer, and applying a hole injection layer that is located in the organic light-emitting device between the anode layer and the light-emitting layer and in contact with the anode layer. The hole-injection layer comprises a conductive polymer, comprising substituted or unsubstituted thiophene repeat units, and a non-conductive material.

### SUMMARY OF THE INVENTION

This invention relates to organic light-emitting devices and methods of making the same.

### BACKGROUND OF THE INVENTION

Electronic devices comprising active organic materials are attracting increasing attention for use in devices such as organic light emitting diodes, organic photovoltaic devices, organic photosensors, organic transistors and memory array devices. Devices comprising organic materials offer benefits such as low weight, low power consumption and flexibility. Moreover, use of soluble organic materials allows use of solution processing in device manufacture, for example inkjet printing or spin-coating.

A typical organic light-emissive device (“OLED”) is fabricated on a glass or plastic substrate coated with a transparent anode such as indium-tin-oxide (“ITO”). A layer of a thin film of at least one electroluminescent organic material is provided over the first electrode. Finally, a, cathode is provided over the layer of electroluminescent organic material.

In operation, holes are injected into the device through the anode and electrons are injected into the device through the cathode. The holes and electrons combine in the organic light-emitting layer to form excitons which then undergo radiative decay to give light.

In WO90/13148 the organic light-emissive material is a conjugated polymer such as poly(phenylenevinylene). In U.S. Pat. No. 4,539,507 the organic light-emissive material is of the class known as small molecule materials, such as tris-(8-hydroxyquinoline) aluminium (“Alq₃”).

Charge transporting, charge injecting or charge blocking layers may be provided between the anode and the light-emitting layer and/or between the cathode and the light-emitting layer.

WO 98/04610 discloses an OLED wherein a hole-injecting layer of poly(ethylenedioxythiophene)polystyrene sulfonate is provided between the anode and the light-emitting layer.

US 2008/0248313 and WO 2009/111675 disclose a conductive composition comprising a sulfonated polythiophene and poly(4-vinylphenol).

### SUMMARY OF THE INVENTION

The invention provides a method of forming an organic light-emitting device comprising an anode, a cathode and at least one light-emitting layer between the anode and the cathode, the method comprising the steps of:

providing an anode layer supported on a surface of the substrate, wherein the anode layer comprises indium tin oxide formed by sputtering indium-tin oxide onto the substrate surface at a substrate surface temperature of less than 100° C., and

applying the at least one light-emitting layer and the cathode over the anode layer.

Optionally, the method comprises the step of applying a hole injection layer that is located in the organic light-emitting device between the anode layer and the light-emitting layer and in contact with the anode layer.

Optionally, the hole-injection layer comprises a conductive material and a non-conductive material.

Optionally, the conductive material is a conductive polymer.

Optionally, the conductive polymer comprises substituted or unsubstituted thiophene repeat units.

Optionally, the thiophene repeat units include sulfonated thiophene repeat units

Optionally, the conductive polymer is a copolymer.

Optionally, about 25%-90% of the polymer repeat units are sulfonated thiophene repeat units.

Optionally, the thiophene repeat units include thiophene repeat units substituted with a polyether group.

Optionally, the non-conductive material is a polymer.

Optionally, the non-conductive polymer is an optionally substituted polystyrene.

Optionally, the non-conductive polymer is optionally substituted poly(vinylphenol).

Optionally, a weight ratio of the conductive material:the non-conductive material is 1:n wherein n is in the range of 1-20.

Optionally, n is no more than 5, optionally no more than 3.

Optionally, the anode is supported on a flexible substrate.

Optionally, the substrate is not heated during sputtering of indium-tin oxide.

Optionally, the method comprises the steps of forming the hole injection layer over the anode layer; forming the at least one light-emitting layer over the hole-injection layer; and forming the cathode over the light-emitting layer.

Optionally, the hole injection layer is formed by depositing a formulation comprising the conductive material, the non-conductive material and at least one solvent onto the layer comprising indium-tin oxide, and evaporating the at least one solvent.

Optionally, the method comprises the step of forming the anode layer by sputtering indium-tin oxide onto the substrate surface at a substrate surface temperature of less than 100° C.

### DESCRIPTION OF THE DRAWINGS

The invention will now be described in more detail with reference to the drawings, wherein:

FIG. 1 illustrates an OLED according to an embodiment of the invention;

FIG. 2 is the x-ray diffraction spectrum of a high-crystallinity indium tin oxide;

FIG. 3 is the x-ray diffraction spectrum of a low-crystallinity indium tin oxide;

FIG. 4 illustrates an inket-printed pixel of a device according to an embodiment of the invention;

FIG. 5 is a graph of lifetime of a device according to an embodiment of the invention and comparative devices; and

FIG. 6 is a graph of voltage stability of a device according to an embodiment of the invention and two comparative devices; and

FIG. 7 is a graph illustrating hole supply in devices according to embodiments of the invention and a comparative device.

### DETAILED DESCRIPTION OF THE INVENTION

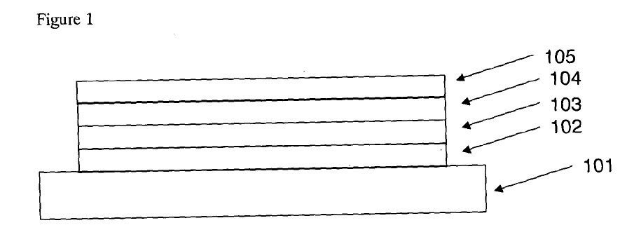

FIG. 1 illustrates an OLED comprising an anode comprising a layer of ITO 102 supported on an opaque or transparent substrate 101, a hole injection layer 103, a light-emitting layer 104 and a cathode 105.

One or more further layers (not shown) may be provided between the anode and cathode, for example one or more layers selected from a hole transporting layer and/or an electron blocking layer between the hole injection layer 103 and the light-emitting layer 104; an electron-transporting layer and/or a hole-blocking layer between the cathode 105 and the light-emitting layer 104; and one or more further light-emitting layers. In one preferred embodiment, a hole-transporting layer is provided between the hole injection layer 103 and the light-emitting layer 104.

At least one of the anode and cathode is transparent so that light emitted from light-emitting layer 104 may be emitted from the device, and the other of the anode and cathode may provide a reflective surface for reflection of light towards the transparent electrode.

In the case of a transparent cathode device, a layer of a reflective material (not shown), for example a metal, may be provided between the substrate and ITO layer 102 so that light emitted from light-emitting layer 104 towards ITO layer 102 is reflected for emission through the transparent cathode.

The OLED may be fabricated by depositing in the appropriate sequence the hole injection layer 103, the light-emitting layer 104, the cathode 105 and any further layers over the substrate 101 carrying ITO layer 102. In another arrangement, the OLED may be fabricated by lamination of substrate 101 carrying ITO layer 102 and a substrate carrying cathode 105, wherein the layers of the OLED between the anode or cathode are provided on the substrate 101 carrying ITO layer 102 and/or on the substrate carrying cathode 105.

Anode

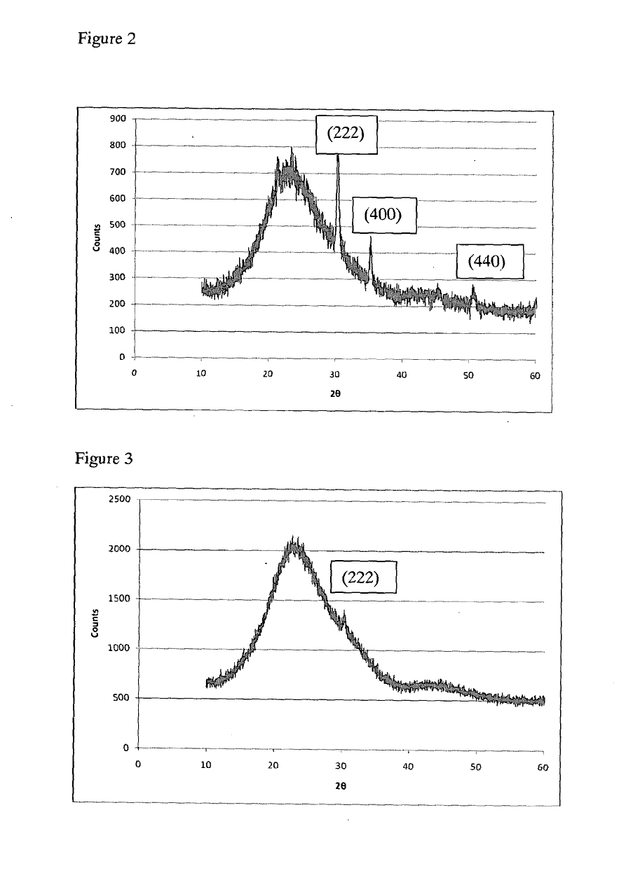

Anode layer 102 is formed from low crystallinity ITO. FIGS. 2 and 3 are the x-ray diffraction spectra for high- and low-crystallinity ITO, respectively. The peaks at (222), (400) and (440) that are characteristic of high-crystallinity ITO are highlighted in FIG. 2. These peaks are very small or entirely absent in FIG. 3, indicative of low crystallinity or amorphous ITO.

ITO layer 102 may be formed by sputtering ITO onto substrate 101. In one embodiment, the surface onto which the ITO is sputtered may simply be a glass or plastic surface of substrate 101. In another embodiment, substrate 101 may carry drive circuitry covered with a planarization layer, and ITO may be sputtered onto a surface of the planarization layer. In a yet further embodiment, the substrate may carry a layer of reflective metal (either directly on the surface of substrate 101 or on the surface of a planarization layer) onto which the ITO is sputtered.

Low crystallinity ITO layer 102 may be formed by sputtering ITO onto a low temperature substrate, for example a substrate at a temperature of less than 100° C., less than 50° C. or at ambient temperature. In one arrangement the ITO layer 102 may be formed by sputtering onto a substrate 101 that is not heated at the time of ITO sputtering, although the substrate may be subjected to heat treatment before or after ITO deposition, for example a drying treatment prior to ITO deposition.

If ITO layer 102 requires patterning, for example patterning in stripes for a passive matrix OLED having cathode stripes substantially perpendicular to the anode ITO stripes, or patterned to form individual pixel electrodes for an active matrix OLED, then the ITO layer 102 may be patterned using methods known to the skilled person, for example photolithography.

Hole Injection Layer

The hole injection layer 103 comprises a conducting material and a non-conducting material.

The conductive polymer is preferably a polymer comprising substituted or unsubstituted thiophene repeat units. The hole injection layer 103 optionally has a thickness in the range of 5-500 nm, optionally 10-200 nm or 10-100 nm. The thickness of the hole injection layer may be selected so that the cavity defined by the anode and cathode is of a size to maximise light emission of a wavelength of light-emitted by the light-emitting layer.

Exemplary conducting polymers are conjugated polymers comprising thiophene repeat units of formula (I):

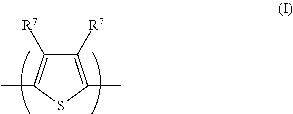

wherein R⁷ independently in each occurrence represents H or a substituent.

The conductive polymer preferably comprises repeat units of formula (I) wherein at least one R⁷ is an acid group, preferably a sulfonic acid group.

The conductive polymer preferably comprises repeat units wherein at least one group R⁷ is a polar, aprotic substituent, for example a polyether group.

The polymer may comprise repeat units carrying one of an acid group and a polar aprotic group and/or repeat units carrying both of an acid group and a polar aprotic group.

An exemplary conductive polymer comprises repeat units of formulae (Ia) and (Ib):

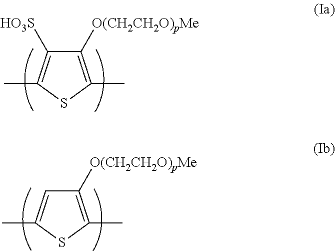

wherein p is at least 1 and is preferably 2.

A sulfonated polymer of this type may be formed by sulfonation of a regioregular polymer comprising repeat units of formula (I) substituted with a polyether group, for example a repeat units of formula (Ib). A polymer of this type is available from Plextronics, Inc. under the trade name Plexcore®.

In one embodiment, the conductive polymer is a polythiophene wherein substantially all repeat units of the polymer are repeat units of formula (I), for example a copolymer consisting essentially of repeat unit of formula (Ia) and (Ib). The polymer may be a random, block or alternating copolymer.

The non-conducting material is preferably a polymer having a substantially non-conjugated polymer backbone.

An exemplary non-conducting polymer is polystyrene substituted with one or more polar, protic groups, for example a polymer comprising repeat units of formula (III):

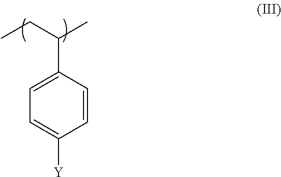

wherein Y is a polar group, for example OH.

An exemplary non-conducting polymer is poly-4-vinylphenol (PVP).

The hole-injection layer is formed by depositing a composition comprising the conducting material, the non-conducting material and one or more solvents, and evaporating the solvents. Solvents may be evaporated using heat and/or vacuum.

The composition may comprise water and at least one organic solvent that is miscible with water. Suitable solvents are shown in Table 1.

TABLE 1

| | CAS | Bp, C. |
|---|---|---|
| 2-butoxyethanol | 11-76-2 | 169 |
| gamma- | | |
| butyrolactone | 96-48-0 | 204 |
| Triethylene glycol | 112-27-6 | 288 |
| 1,3-propanediol | 504-63-2 | 214 |
| DMSO | 67-68-5 | 189 |
| 1,2-propanediol | 57-55-6 | 187 |
| 1,3-butanediol | 107-88-0 | 203 |
| 1,2-butanediol | 584-03-2 | 192 |
| Diethylene glycol | 111-46-6 | 245 |
| Ethylene glycol | 107-21-1 | 195 |
| glycerol | 56-81-5 | 290 |

A particularly suitable solvent comprises 30-40% 2-butoxyethanol and 60-70% water.

Suitable deposition methods include spin and dip coating and printing methods.

Exemplary coating methods include spin-coating, dip-coating, roll coating or roll-to-roll printing, doctor blade coating, slot die coating.

Exemplary printing methods include roll-printing, flexographic printing, gravure printing, screen printing and inkjet printing.

Coating methods, such as those described above, are particularly suitable for devices wherein patterning is unnecessary—for example for lighting applications or simple monochrome segmented displays.

Printing is particularly suitable for high information content displays, in particular full colour displays.

The light-emitting layer 104, and any charge-transporting, charge blocking or additional light-emitting layers, may be deposited using a method that is the same as or different to the method used to deposit the hole injection layer 103. In one preferred arrangement, the hole injection layer 103 and the light-emitting layer 104 are deposited from solution.

A device may be inkjet printed by providing a patterned layer over the anode and defining wells into which the hole injection material and a light-emitting material is printed. A light-emitting material having one colour of emission may be printed into each well the case of a monochrome device, or multiple light-emitting materials of different colours may be printed in the case of a multicolour, in particular full colour device. The patterned layer is typically a layer of photoresist that is patterned to define wells, for example as described in EP 0880303.

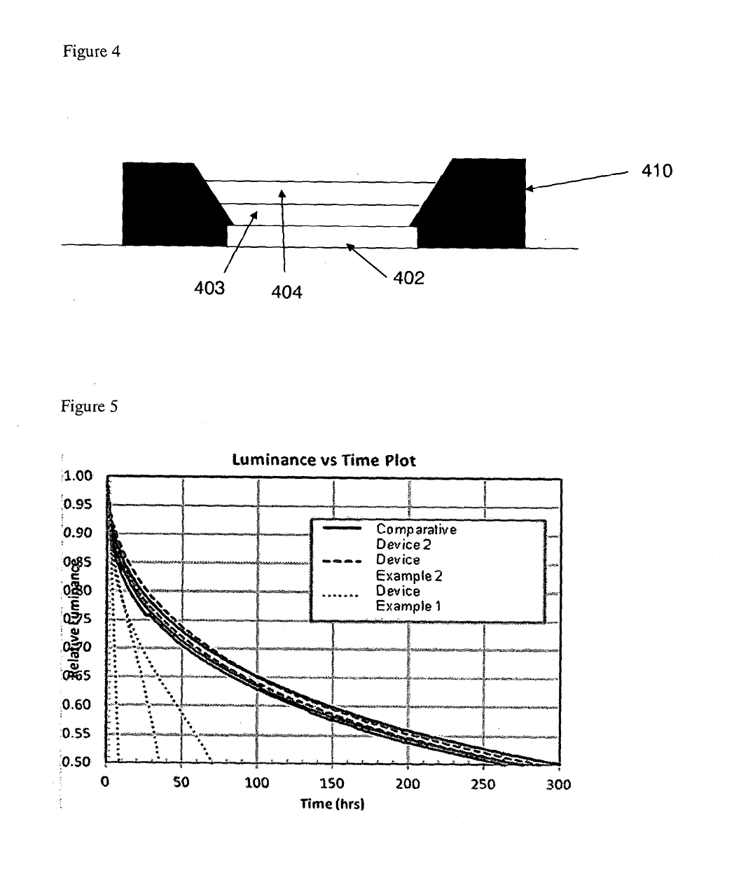

With reference to FIG. 4, a pixel of a display having a structure shown in FIG. 1 comprises anode layer 402 comprising a plurality of anodes of which one anode 402 is shown, and a patterned layer of photoresist 410 defining a well over each anode. The hole-injection layer 403 and light-emitting layer 404 are formed by inkjet printing into each well. Further layers may be printed into each well, for example a hole-transporting layer between the anode and the light-emitting layer and/or one or more further light-emitting layers.

As an alternative to wells, the ink may be printed into channels defined within a patterned layer. In particular, the photoresist may be patterned to form channels which, unlike wells, extend over a plurality of pixels and which may be closed or open at the channel ends.

Cathode

Cathode 105 may consist of a single layer of a conductive material, such as a layer of metal (e.g. aluminium) or a metal alloy. Alternatively, it may comprise a plurality of layers.

Cathode 105 may be transparent or opaque. In the case where cathode 105 is opaque, it may provide a reflective surface to light emitted from light-emitting layer 104 towards cathode 105.

Exemplary cathodes 105 comprising multiple layers include:
one or more layers of a high workfunction material (e.g. greater than 3.5 eV) and a layer of a lower workfunction material (e.g. less than 3.5 eV or less than 3 eV) between the light-emitting layer 304 and the one or more layers of high workfunction material, for example as disclosed in WO 98/10621, WO 98/57381, Appl. Phys. Lett. 2002, 81(4), 634 and WO 02/84759. Exemplary cathodes include bilayer cathodes, for example Ba/Al or Ca/Al, or trilayer cathodes, for example Ca/Al/Ag.
one or more conductive layers, such as one or more metal layers, and a thin layer of metal compound between the light-emitting layer and the one or more conductive layers.

Exemplary metal compounds include an oxide or fluoride of an alkali or alkali earth metal, for example lithium fluoride as disclosed in WO 00/48258; barium fluoride as disclosed in Appl. Phys. Lett. 2001, 79(5), 2001; and barium oxide. The metal compound layer may have a thickness of no more than 5 nm. The one or more conductive layers preferably includes at least one layer of a high workfunction material, for example a high workfunction metal (e.g. greater than 3.5 eV). Exemplary cathodes include bilayer cathodes, for example LiF/Al, or trilayer cathodes, for example LiF/Al/Ag or LiF/Ca/Al.

Exemplary low workfunction materials include low workfunction metals, for example calcium or barium. Exemplary high workfunction materials include high workfunction metals, for example aluminium or silver. Work functions of metals can be found in, for example, Michaelson, J. Appl. Phys. 48(11), 4729, 1977.

An exemplary transparent cathode comprises a layer of a metal that is sufficiently thin to allow light to pass through it. The thickness of a metal layer required for transparency of that layer will depend on the metal, however it is preferred that a metal layer of a transparent cathode has a thickness of less than 20 nm. A preferred transparent metal is silver.

The layer of transparent metal may be overlaid with another layer to form a bilayer transparent cathode, for example metal/ITO and metal/SiO.

Another transparent cathode structure comprises a layer of an n-doped organic semiconductor, for example an electron-transporting layer doped with an organic or inorganic donor capped with a layer of transparent, conductive material, for example a layer of ITO.

A device having a transparent cathode is particularly advantageous for active matrix OLED devices comprising drive circuitry on substrate 101 because emission through a transparent anode in such devices is at least partially blocked by the drive circuitry.

The thickness of a metal layer required to provide opacity or reflectivity depends on the material, however a preferred thickness is at least 50 nm.

Charge Transporting Layers

A hole transporting layer may be provided between the hole-injection layer 103 and the light-emitting layer 104 (or light-emitting layers). Likewise, an electron transporting layer may be provided between the cathode and the light-emitting layers.

Similarly, an electron blocking layer may be provided between the hole-injection layer and the light-emitting layer and a hole blocking layer may be provided between the cathode and the light-emitting layer. Transporting and blocking layers may be used in combination.

Depending on its HOMO and LUMO levels, a single layer may both transport one of holes and electrons and block the other of holes and electrons.

If present, a hole transporting layer located between the hole-injection layer and the light-emitting layers preferably has a HOMO level of less than or equal to 5.5 eV, more preferably around 4.8-5.5 eV. The HOMO level of the hole transport layer may be selected so as to be within 0.2 eV, optionally within 0.1 eV, of an adjacent layer (such as a light-emitting layer) in order to provide a small barrier to hole transport between these layers.

If present, an electron transporting layer located between the light-emitting layers and cathode preferably has a LUMO level of around 3-3.5 eV. HOMO and LUMO levels may be measured by cyclic voltammetry.

A hole transporting layer may contain a hole-transporting (hetero)arylamine, such as a homopolymer or copolymer comprising hole transporting repeat (hetero)arylamine repeat units.

Exemplary (hetero)arylamine repeat units have formula (IV):

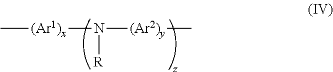

wherein Ar¹ and Ar² in each occurrence are independently selected from optionally substituted aryl or heteroaryl groups, z is greater than or equal to 1, preferably 1 or 2, R is H or a substituent, preferably a substituent, and x and y are each independently 1, 2 or 3.

R is preferably alkyl, for example C₁₋₂₀ alkyl, Ar³, or a branched or linear chain of Ar³ groups, for example —(Ar³)ᵣ, wherein Ar³ in each occurrence is independently selected from aryl or heteroaryl and r is at least 1, optionally 1, 2 or 3.

Any of Ar¹, Ar² and Ar³ may independently be substituted with one or more substituents. Preferred substituents are selected from the group R³ consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR⁵₂, OR⁵; SR⁵,
fluorine, nitro and cyano, and
crosslinkable groups;

wherein each R⁴ is independently alkyl, for example C₁₋₂₀ alkyl, in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups.

R may comprise a crosslinkable-group, for example a group comprising a polymerisable double bond such and a vinyl or acrylate group, or a benzocyclobutane group such that the hole-transporting layer may be crosslinked following its deposition, in particular if the light-emitting layer is deposited from solution.

Any of the aryl or heteroaryl groups in the repeat unit of Formula (IV) may be linked by a direct bond or a divalent linking atom or group. Preferred divalent linking atoms and groups include O, S; substituted N; and substituted C.

Where present, substituted N or substituted C of R³, R⁴ or of the divalent linking group may independently in each occurrence be NR⁶ or CR⁶₂ respectively wherein R⁶ is alkyl or optionally substituted aryl or heteroaryl. Optional substituents for aryl or heteroaryl groups R⁶ may be selected from R⁴ or R⁵.

In one preferred arrangement, R is Ar³ and each of Ar¹, Ar² and Ar³ are independently and optionally substituted with one or more C₁₋₂₀ alkyl groups.

Ar¹, Ar² and Ar³ are preferably phenyl, each of which may independently be substituted with one or more substituents as described above, preferably one or more C₁₋₂₀ alkyl groups.

In another preferred arrangement, Ar¹, Ar² and Ar³ are phenyl, each of which may be substituted with one or more C₁₋₂₀ alkyl groups, and r=1.

In another preferred arrangement, Ar¹ and Ar² are phenyl, each of which may be substituted with one or more C₁₋₂₀ alkyl groups, and R is 3,5-diphenylbenzene wherein each phenyl may be substituted with one or more alkyl groups.

Arylamine repeat units may be provided in a copolymer in an amount of at least 1 mol %, optionally at least 5 mol %.

Exemplary copolymers comprise repeat units of formula (IV) and optionally substituted (hetero)arylene co-repeat units. Exemplary arylene co-repeat units are disclosed in for example, Adv. Mater. 2000 12(23) 1737-1750 and include: phenylene repeat units, for example 1,4-linked phenylene repeat units; fluorene repeat units, for example 2,7-linked fluorene repeat units, indenofluorene repeat units and spirobifluorene repeat units.

Phenylene repeat units are disclosed in, for example, J. Appl. Phys. 1996, 79, 934; 2,7-fluorene repeat units are disclosed in, for example, EP 0842208; indenofluorene repeat units are disclosed in, for example, Macromolecules 2000, 33(6), 2016-2020; and spirobifluorene repeat units are disclosed in, for example EP 0707020.

Each of these repeat units is optionally substituted. Examples of substituents include solubilising groups such as C₁₋₂₀ alkyl or alkoxy; electron withdrawing groups such as fluorine, nitro or cyano; crosslinkable-groups, for example groups comprising a polymerisable double bond such and a vinyl or acrylate group, or a benzocyclobutane group; and substituents for increasing glass transition temperature (Tg) of the polymer.

Light-Emitting Layer

Suitable organic light-emitting materials for use in light-emitting layer 104 include non-polymeric (small molecule), polymeric and dendrimeric light-emitting materials.

Exemplary light-emitting polymers include polymers having a non-conjugated backbone with light-emitting groups in polymer side-groups, and polymers having a conjugated backbone with light-emitting groups in the backbone of the polymer and/or in polymer end-groups or side-groups. Exemplary conjugated light-emitting polymers include polyarylenevinylenes, for example polyphenylenevinylenes, and polymers comprising arylene and/or arylamine repeat units as described above with reference to charge-transporting layers.

The light-emitting layer may consist only of a light-emitting material or it may comprise one or more further materials, for example one or more charge-transporting materials.

The light-emitting layer may comprise a semiconducting host material and a fluorescent or phosphorescent light-emitting dopant, for example a light-emitting transition metal complex dopant.

The light-emitting layer may be formed by any process, including solution deposition methods as described above, or evaporation of the material or materials forming the light-emitting layer.

The device may comprise more than one light-emitting layer. For example, a white light-emitting OLED may comprise a plurality of light-emitting layers that, in combination, provide white light.

Substrate

Substrate 101 may be a layer of glass or plastic. If light is emitted from the device through ITO layer 102 then substrate 101 is transparent. The substrate may include drive circuitry for forming an active matrix device. The substrate may include a reflective metal layer onto which the ITO is sputtered, for example in order to provide a reflective surface for a transparent cathode device.

The substrate 101 may be a material that is sensitive to temperatures in excess of 100° C., for example a polymeric substrate with a glass transition temperature in the range of 100° C.-200° C. and as such suitable for sputtering of ITO at temperatures below 100° C.

The substrate may be flexible or rigid. The low crystallinity ITO layer 102 may be particularly suitable for use with flexible substrates.

Encapsulation

Organic light-emitting devices tend to be sensitive to moisture and oxygen. Accordingly, the substrate 101 preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### EXAMPLES

### General Device Process

Organic light-emitting devices having the following structure were formed on a glass substrate:

ITO (45 nm)/HIL (35 nm)/HTL (22 nm)/EL (70 nm)/Cathode

wherein ITO is deposited onto a glass substrate by pulsed DC sputtering in an argon/oxygen atmosphere at a power of 2 kW and at a pressure of 5×10⁻³ mbar; HIL is a layer of hole-injection material comprising a conductive polymer having repeat units of formulae (Ia) and (Ib) and the non-conductive polymer poly(4-vinylphenol); HTL is a hole transport layer comprising a crosslinked hole transporting polymer; EL is a light-emitting layer formed from a blue-light-emitting polymer; and Cathode is a cathode comprising a layer of a metal fluoride, a layer of aluminium and a layer of silver.

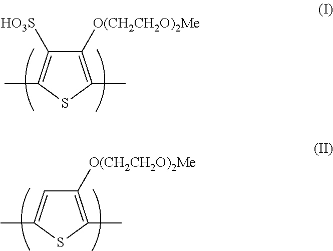

Each of HIL, HTL and EL were formed by spin-coating.

The hole transporting polymer was crosslinked following deposition to avoid dissolution of this layer during deposition of the light-emitting layer.

The substrate was not heated during deposition.

### Device Example 1

A device was prepared according to the general device process, using a HIL in which the conductive polymer:non-conductive weight ratio of the polymer was 1:14.

### Device Example 2

A device was prepared as per Device Example 1, except that the conductive polymer:non-conductive weight ratio of the polymer was 1:5.5.

### Device Example 3

A device was prepared as per Device Example 1, except that the conductive polymer:non-conductive weight ratio of the polymer was 1:1.5.

The solvent for the HiL in these examples comprised 35% 2-butoxyethanol and 65% water.

The active component content (solids content) of the HiL solution was 18 wt %, but active component contents between 6 and 40 wt % can typically be used.

### Comparative Devices 1-3

Comparative Devices 1-3 were prepared as per Device Examples 1-3 respectively, except that commercially available high crystallinity ITO on a glass substrate was used.

With reference to FIG. 5, Device Example 2, having a higher content of the conductive polymer in the hole injection layer than Device Example 1, had a significantly longer half-life than Device Example 1, and a half-life comparable to Comparative Device 2 having high crystallinity ITO (“half-life” as used with reference to device lifetime means the time taken for luminance to fall by 50% at constant current).

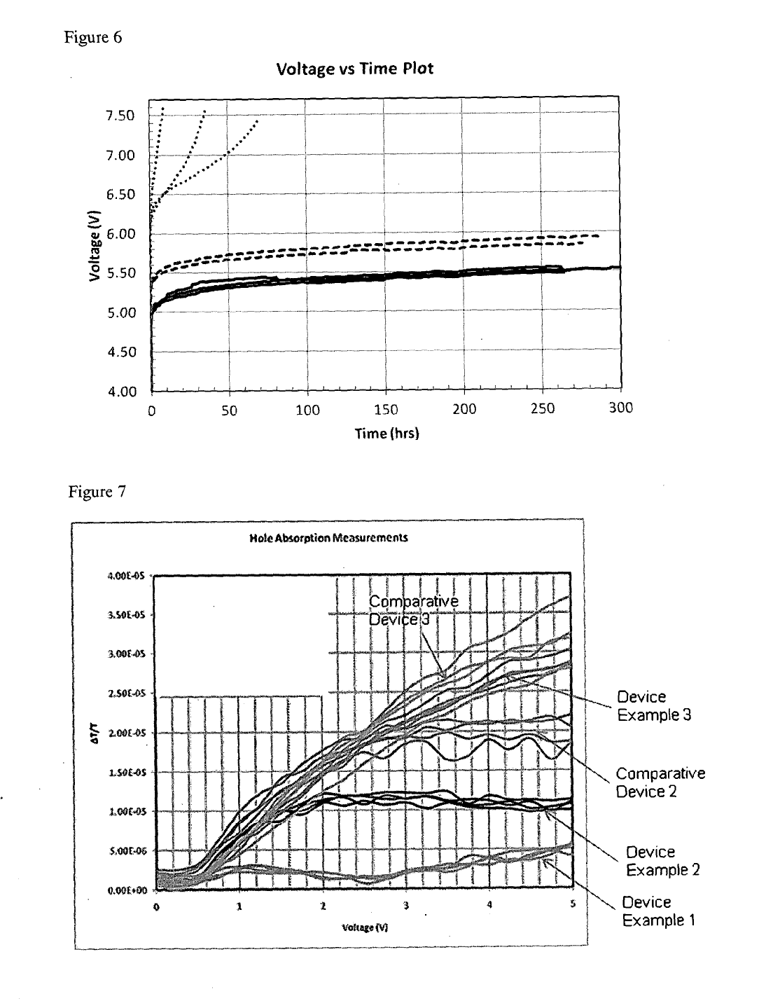

With reference to FIG. 6, the voltage required to drive Device Example 2 is substantially more stable over time than the voltage required for Device Example 1, and again is comparable to Comparative Device 2.

Without wishing to be bound by any theory, it is believed that low crystallinity ITO may provide poor hole supply as compared to higher crystallinity ITO, resulting in loss of device performance, and that this loss of hole supply may be recovered by using a hole injection layer with a relatively high conductive polymer content.

FIG. 7 illustrates that Device Example 3 has substantially the same hole supply as Comparative Device 3. Accordingly, by selection of the amount of conductive polymer in the hole injection layer it may be possible to form devices having low crystallinity ITO anodes with device performance that is the same as or similar to devices with high crystallinity ITO anodes.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A method of forming an organic light-emitting device comprising an anode, a cathode and at least one light-emitting layer between the anode and the cathode, the method comprising the steps of:
providing an anode layer supported on a surface of the substrate, wherein the anode layer comprises indium tin oxide formed by sputtering indium-tin oxide onto the substrate surface at a substrate surface temperature of less than 100° C., and
applying the at least one light-emitting layer and the cathode over the anode layer.

2. The method according to claim 1, further comprising a step of applying a hole injection layer that is located in the organic light-emitting device between the anode layer and the light-emitting layer and in contact with the anode layer.

3. The method according to claim 2, wherein the hole-injection layer comprises a conductive material and a non-conductive material.

4. The method according to claim 3, wherein the conductive material is a conductive polymer.

5. The method according to claim 4, wherein the conductive polymer comprises substituted or unsubstituted thiophene repeat units.

6. The method according to claim 5, wherein the thiophene repeat units include sulfonated thiophene repeat units.

7. The method according to claim 4, wherein the conductive polymer is a copolymer.

8. The method according to claim 6, wherein about 25%-90% of the polymer repeat units are sulfonated thiophene repeat units.

9. The method according to claim 5, wherein the thiophene repeat units include thiophene repeat units substituted with a polyether group.

10. The method according to claim 3, wherein the non-conductive material is a polymer.

11. The method according to claim 10, wherein the non-conductive material is an optionally substituted polystyrene.

12. The method according to claim 11, wherein the non-conductive material is optionally substituted poly(vinylphenol).

13. The method according to claim 3, wherein a weight ratio of the conductive material:the non-conductive material is 1:n, wherein n is in the range of 1-20.

14. The method according to claim 13, wherein n is no more than 5.

15. The method according to claim 1, wherein the anode is supported on a flexible substrate.

16. The method according to claim 1, wherein the substrate is not heated during sputtering of indium-tin oxide.

17. The method according to claim 2, further comprising steps of:
forming the hole injection layer over the anode layer;
forming the at least one light-emitting layer over the hole-injection layer; and
forming the cathode over the light-emitting layer.

18. The method according to claim 3, wherein the hole injection layer is formed by depositing a formulation comprising the conductive material, the non-conductive material and at least one solvent onto the layer comprising indium-tin oxide, and evaporating the at least one solvent.

19. The method according to claim 1, comprising a step of forming the anode layer by sputtering indium-tin oxide onto the substrate surface at a substrate surface temperature of less than 100° C.
